(19) United States
(12) Patent Application Publication
(10) Pub. No.: US 2016/0076138 A1
(43) Pub. Date: Mar. 17, 2016

(54) SPRAY REJUVENATION OF SPUTTERING TARGETS

(71) Applicants: Christopher MICHALUK, Tucson, AZ (US); William LOEWENTHAL, Chesterland, OH (US); Gary ROZAK, Akron, OH (US); Marc ABOUAF, Harvard, MA (US); Patrick HOGAN, Somerville, MA (US); Steven A. MILLER, Canton, MA (US)

(72) Inventors: Christopher MICHALUK, Tucson, AZ (US); William LOEWENTHAL, Chesterland, OH (US); Gary ROZAK, Akron, OH (US); Marc ABOUAF, Harvard, MA (US); Patrick HOGAN, Somerville, MA (US); Steven A. MILLER, Canton, MA (US)

(21) Appl. No.: 14/950,249

(22) Filed: Nov. 24, 2015

Related U.S. Application Data
(63) Continuation of application No. 13/713,632, filed on Dec. 13, 2012.
(60) Provisional application No. 61/576,653, filed on Dec. 16, 2011.

(51) Int. Cl. C23C 14/34; C23C 24/04

(52) U.S. Cl. CPC C23C 14/3414; C23C 24/04

(57) ABSTRACT

In various embodiments, used sputtering targets are refurbished at least in part by maintaining a large obliquity angle between the spray-deposition gun and the depressed surface contour of the target during spray deposition of the target material.

### RELATED APPLICATION

This application claims the benefit of and priority to U.S. Provisional Patent Application No. 61/576,653, filed Dec. 16, 2011, the entire disclosure of which is hereby incorporated herein by reference.

### TECHNICAL FIELD

In various embodiments, the present invention relates to spray deposition of metallic and/or non-metallic powders, in particular cold-spray deposition for rejuvenation of sputtering targets.

### BACKGROUND

Sputtering, a physical-vapor-deposition technique, is utilized in many industries to deposit thin films of various materials with highly controllable composition and uniformity on any of a variety of substrates. In a sputtering process, a sputtering target of a the material to be deposited (or a component thereof) is subjected to bombardment by energetic particles, which thus eject atoms of the target material toward the substrate. Conventional new (i.e., unused) planar sputtering targets have flat round or flat quasi-rectangular shapes. For example, FIG. 1 depicts a new sputtering target 100 idealized as a rectangular prism. (In reality, planar sputtering targets are typically quasi-rectangular with rounded corners or are even round.) During sputtering, this shape is eroded away, and by the target's “end of life” (i.e., the point at which the used target is replaced by a new pristine target), typically only a portion of the target material has been utilized. Thus, the user of the sputter target typically must discard the remaining target material (and thus most of the remaining value of the original target). As described in U.S. Patent Application Publication Nos. 2008/0216602 and 2008/0271779 (the entire disclosures of which are incorporated by reference herein), this utilization dynamic makes sputter targets good candidates for refurbishment via spray deposition, e.g., cold spray.

However, sputtering targets are typically eroded away in a manner that provides a highly irregular surface at the target's end of life. This irregular surface is characterized by variations in width at different depths, different depths of penetration along the surface, and surfaces with widely varying angles to the original surface, as shown in FIG. 2, which illustrates the varying surface profile of portions of a used sputter target. The irregular and/or complex surface of a used sputtering target tends to compromise the efficacy of a spray refurbishment process; for example, if the spray deposition is even effective on such surfaces, the deposited material tends to be weakly bonded and have unacceptably high levels of porosity. Furthermore, spray of composite powders (i.e., mixtures of multiple elements) on such irregular and/or complex surfaces tends to result in local composition variations. Thus, there is a need for an improved spray rejuvenation process for eroded sputter targets that provides refurbished targets having properties (e.g., microstructural properties, porosity, bonding strength) on par with those of the original target.

### SUMMARY

Embodiments of the present invention enable the efficient and effective refurbishment of used (i.e., eroded) sputter targets via spray deposition (e.g., cold spray) by maintaining the obliquity angle between each localized portion of the irregular surface and the spray-deposition jet (i.e., the stream of powder propelled from the deposition apparatus and impinging on the target surface) larger than approximately 45° (and preferably larger than approximately 60°). FIG. 3 schematically illustrates an obliquity angle 300 between a jet of particles 310 from a spray-deposition gun 320 and a target surface 330. As shown, the obliquity angle 300 has a maximum possible value of 90°. Maintaining the obliquity angle within the preferred range of approximately 45° to approximately 90° enables the filling of the eroded areas of the used sputter target with a spray-deposited layer that has low porosity, a non-gaseous impurity content similar to that of the spent sputtering target, grain size and chemical homogeneity equal to or finer than the spent target (e.g., a wrought target not originally formed by spray deposition), and a high-quality mechanical and/or metallurgical bond to the target material.

Moreover, preferred embodiments of the invention involve spray deposition of the target material to refurbish a used sputter target having a maximum surface depth (i.e., the difference between the maximum penetration and minimum penetration (e.g., the original top surface and/or top surface after refurbishment) in the used target) less than 9 mm, and preferably less than 6 mm, or even less than 3 mm.

Advantageously and surprisingly, embodiments of the invention utilizing the above-described preferred obliquity angles during spray refurbishment provide high-quality spray-deposited regions while requiring no sophisticated spray-control software, surface-imaging systems, or robotics capable of complex (e.g., non-rectilinear) motions. Attempts to refurbish spent sputter targets with small obliquity angles typically either result in poor-quality fill regions or require control schemes and multi-axis robotics to adequately fill the spent regions. In contrast, embodiments of the present invention refurbish spent targets inexpensively and relatively simply. Such refurbishment (and the resulting refurbished sputter targets) enable an end user to pay only for the replacement of sputtering materials (many of which are exotic and/or expensive) actually used, rather than for entire targets. Furthermore, in accordance with various embodiments of the invention, the spray refurbishment of the sputter target may be performed with the eroded target still attached to its backing plate, which typically includes or consists essentially of a lower-melting-point material such as copper, aluminum, or stainless steel. For example, the sprayed target material may be deposited by cold spray at temperatures lower than that of the backing plate.

Embodiments of the present invention utilize any of a variety of target materials for the refurbishment process, although the spray-deposited material is preferably that of the spent target. In this manner, targets refurbished in accordance with embodiments of the invention may be utilized (i.e., sputtered) with substantially identical performance and properties of the original unused target, which is typically originally fabricated utilizing non-spray techniques, e.g., cold rolling and/or hot isostatic pressing. In some embodiments, the target material includes or consists essentially of one or more refractory metals, e.g., Mo, Ti, Mo/Ti, Nb, Ta, W, Mo, Zr, and mixtures or alloys thereof. In some embodiments the obliquity angle is increased as a function of the hardness and/or melting point (e.g., Young's modulus) of the target material. For example, harder, more brittle materials (e.g., those less prone to deformation and galling) may be deposited at obliquity angles greater than about 60°, or even greater than about 75°, in order to facilitate formation of a high-quality bond between the sprayed material and the target.

In various embodiments of the invention, an eroded sputter target is provided, the target having a non-planar surface contour. The target material is sprayed over the contour while maintaining the obliquity angle greater than about 45°, and the surface non-planarity of the target is at least partially filled with the sprayed material. In some embodiments, the eroded regions of the target are substantially completely filled, providing a substantially planar surface to the refurbished target. In other embodiments, the eroded regions are overfilled (and the target material may even be sprayed over less-eroded or non-eroded portions of the target), and the target is subsequently machined (e.g., ground) down until its surface is substantially flat. While the eroded target generally has the above-described local surface non-planarities, the target (as shown in FIGS. 1 and 2) continues to define a more global “surface plane” corresponding to the surface of the original (and hence the refurbished) target. In preferred embodiments of the invention, the angle of the jet of sprayed target material relative to this surface plane is approximately 90° during the entire refurbishment process. That is, the angle of the jet (and thus of the spray apparatus) preferably does not change in response to the local non-planarities of the surface of the spent target, simplifying the process and rendering it less expensive and less time-consuming. After the deposition of the target material, the refurbished target may be annealed to strengthen the bond between the spray-deposited material and the original target material. The annealing may be performed at a temperature of, e.g., between approximately 480° C. and approximately 700° C., or even to approximately 900° C., and/or for a time of, e.g., between approximately 1 hour and approximately 16 hours.

Prior to the spray deposition of the target material, the surface of the eroded target may be treated to thus provide a high-quality, clean, substantially oxide-free interface between the original target material and the newly deposited material. For example, the eroded surface may be grit blasted, machined, and/or etched prior to the spray deposition. Embodiments of the invention refurbish spent sputter targets earlier in their life cycle when compared to more conventional refurbishment processes, which may be performed when more than 30%, or even more than 50% of the target material has been eroded away. In contrast, embodiments of the present invention refurbish sputter targets when less than 30% of the target material has been eroded away, and/or when the surface contour of the eroded target (which will correspond to the interface between the original target material and the target material spray deposited during refurbishment) does not form an angle to the original surface plane of the target that exceeds 45° (and in preferred embodiments, the angle does not exceed 30°).

In many embodiments, the interface between the eroded surface of the target and the spray-deposited material is detectable visually and/or by metallographic evaluation. For example, the spray-deposited material may exhibit improved metallurgical character (finer grain size and a finer degree of chemical homogeneity) than the original target material. Furthermore, the interface may be detectable via chemical analysis, as it may incorporate a finite concentration of impurities (e.g., oxygen and/or carbon) that is detectable (i.e., greater than a background level of the target) but that preferably has no deleterious impact on the sputtering process in which the refurbished target is employed.

While the embodiments of the invention detailed herein are mainly described in relation to originally substantially planar sputtering targets, embodiments of the invention may utilize non-planar sputter targets such as hollow-cathode magnetron, rotary, or cylindrical targets, or profiled targets (e.g., such as those described in U.S. Patent Application Publication No. 2011/0303535, the entire disclosure of which is incorporated by reference herein), and targets with life-extending “pads” in regions of anticipated sputtering-induced erosion. While planar targets may be translated (i.e., relative to a spray-deposition gun) in two rectilinear directions to fill eroded regions in spent sputtering targets, rotary targets may be rotated relative to the spray-deposition gun, which may thus need only translate in a single dimension relative to the target.

As used herein, a “backing plate” may be substantially planar, tubular, or cylindrical, depending on the geometry of the sputtering target, and may include or consist essentially of one or more materials having a melting point less than that of the target material and/or less than the temperature of the spray material during spray deposition. Exemplary materials for backing plates include copper, aluminum, and/or stainless steel.

In an aspect, embodiments of the invention feature a method of refurbishing an eroded sputtering target having an eroded region with a depressed surface contour that is non-planar and that defines a maximum surface depth. The eroded sputtering target (i.e., at least a plate thereof) includes or consists essentially of a target material. A spray-deposition gun is positioned over the eroded region, and spray deposition of a jet of particles of the target material is initiated at a first location to partially fill the eroded region, where the obliquity angle between the spray-deposition gun and the eroded region immediately thereunder is approximately 45° or greater. The eroded region is substantially filled by spray-depositing particles of the target material while (i) translating the spray-deposition gun relative to the eroded sputtering target, (ii) changing the obliquity angle to a plurality of different values selected from the range of approximately 45° to approximately 90°, and (iii) at each location over the eroded sputtering target, controlling a deposition rate of the particles of the target material based on a depth of the eroded region at the location.

Embodiments of the invention may include one or more of the following, in any of a variety of combinations. The obliquity angle at the first location may be greater than approximately 60°. The maximum surface depth of the eroded sputter target prior to spray deposition may be less than 9 mm, or even less than 6 mm. Spray depositing the particles of the target material may include or consist essentially of cold spraying. The obliquity angle at the first location may have a first value (e.g., approximately 45° or a value between 45° and 60°). While substantially filling the eroded region, the obliquity angle may change (a) from the first value to approximately 90° and (b) thereafter, from approximately 90° to approximately the first value. The sputtering target may be annealed after substantially filling the eroded region. The annealing may be performed under vacuum. Substantially filling the eroded region may include or consist essentially of overfilling the eroded region to form a refurbished sputter target having a non-planar surface. The non-planar surface may be planarized to form a substantially planar surface of the refurbished sputter target.

The spray-deposition gun may be translated relative to the eroded sputtering target at a substantially constant rate notwithstanding changes in depth of the eroded region during spray deposition. The spray-deposition gun may be translated relative to the eroded sputtering target at a substantially constant rate notwithstanding changes in the obliquity angle during spray deposition. Controlling the deposition rate of the particles of the target material may include or consist essentially of controlling the rate of the translation of the spray-deposition gun relative to the eroded sputtering target. Controlling the deposition rate of the particles of the target material may include or consist essentially of controlling the rate of particle flow to the spray-deposition gun. The spray-deposition gun may be translated relative to the eroded sputtering target only rectilinearly. The target material may be an alloy or mixture of a plurality of different elements. The depth profile of the eroded region may be measured prior to spray deposition.

These and other objects, along with advantages and features of the present invention herein disclosed, will become more apparent through reference to the following description, the accompanying drawings, and the claims. Furthermore, it is to be understood that the features of the various embodiments described herein are not mutually exclusive and may exist in various combinations and permutations. As used herein, the term “cold spray” refers to techniques in which one or more powders are spray-deposited without melting during spraying, e.g., cold spray, kinetic spray, and the like. The sprayed powders may be heated prior to and during deposition, but only to temperatures below their melting points. As used herein, the terms “approximately” and “substantially” mean±10%, and in some embodiments, ±5%. The term “consists essentially of” means excluding other materials that contribute to function, unless otherwise defined herein. Nonetheless, such other materials may be present, collectively or individually, in trace amounts.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 is a schematic isometric representation of an unused planar sputtering target;

FIG. 2 is an isometric view of the depth contour of the eroded region of a used planar sputtering target in accordance with various embodiments of the invention;

FIG. 3 is a schematic representation of the obliquity angle defined during spray deposition in accordance with various embodiments of the invention;

FIG. 4A is an isometric view of a used sputtering target having an eroded region formed therein in accordance with various embodiments of the invention;

FIG. 4B is a cross-sectional view, along line 4B-4B, of the used sputtering target depicted in FIG. 4A;

FIG. 5 is a cross-sectional view of a used sputtering target at the initiation of refurbishment in accordance with various embodiments of the invention;

FIG. 6 is a cross-sectional view of a refurbished sputtering target in accordance with various embodiments of the invention; and

FIG. 7 is a cross-sectional view of a refurbished sputtering target before optional planarization of spray-deposited material in accordance with various embodiments of the invention.

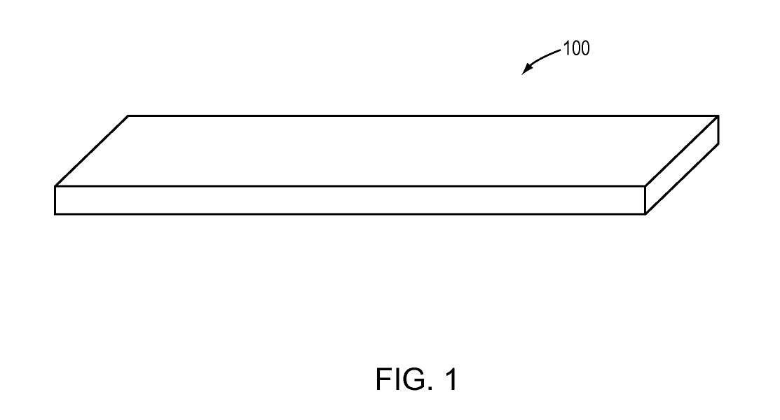

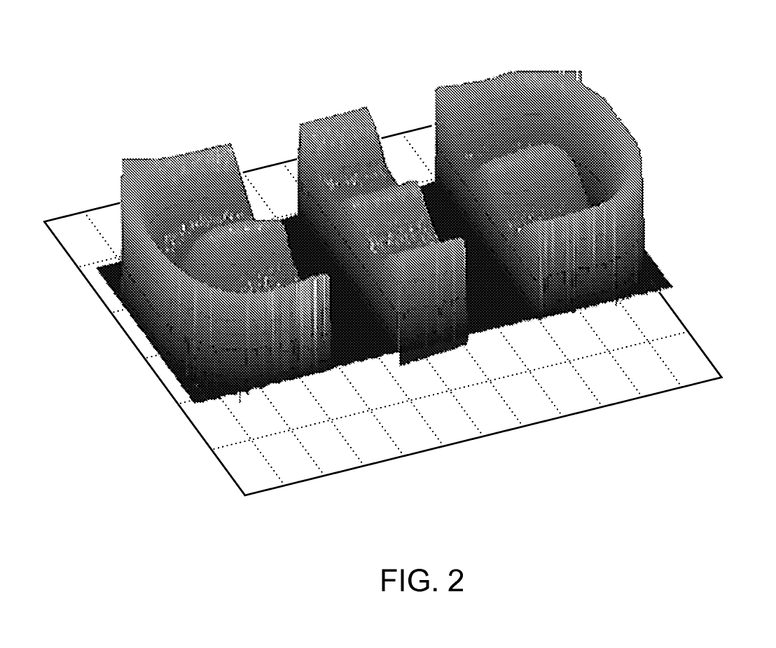

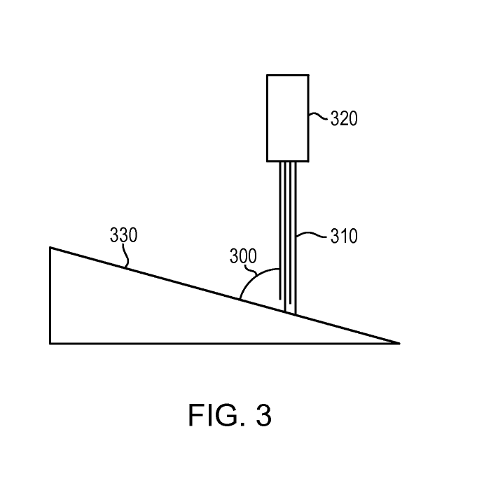

### DETAILED DESCRIPTION

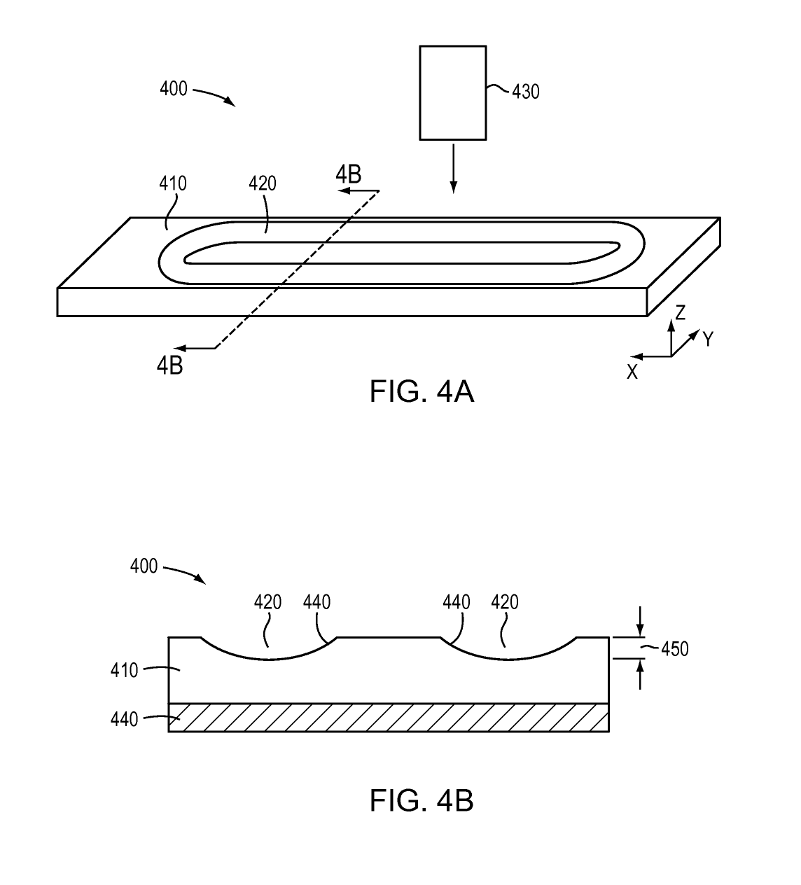

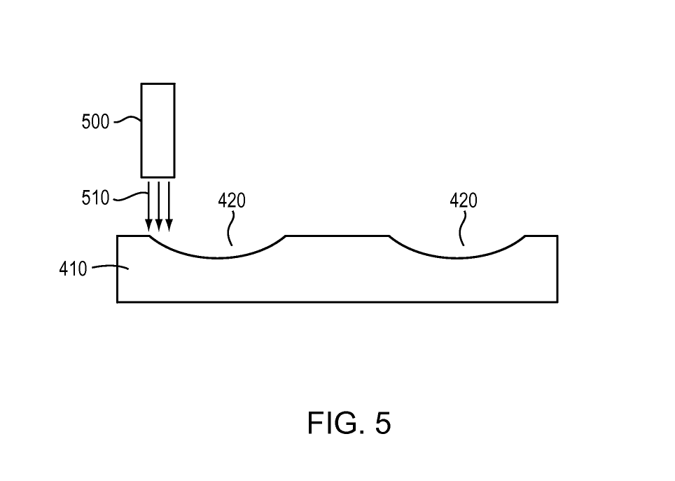

FIG. 4A schematically depicts a used (or “spent”) sputtering target 400 in accordance with various embodiments of the present invention. The sputtering target 400 typically includes or consists essentially of a sputtering-target plate 410 that contains therewithin an eroded region 420 formed by the consumption of the material of plate 410 during sputtering in a sputtering tool. The plate 410 may include or consist essentially of one or more (e.g., as an alloy or mixture) of sputterable materials, e.g., metals. In some embodiments, the target material (i.e., the material of plate 410) includes or consists essentially of one or more refractory metals, e.g., Mo, Ti, Mo/Ti, Nb, Ta, W, Mo, Zr, and mixtures or alloys thereof. The plate 410 is typically bonded or otherwise affixed to a backing plate (not shown in FIG. 4A; see FIG. 4B) for sputtering, but plate 410 may be refurbished in accordance with embodiments of the present invention with the backing plate present or removed. The eroded region 420 typically defines a recessed, non-planar surface contour (as shown in, e.g., FIG. 4B), each point of which defines an obliquity angle 300 with a spray-deposition gun that is typically oriented substantially perpendicular to the more global “surface plane” corresponding to the surface of the original (and hence the refurbished) target. As depicted in FIG. 4A, this surface plane corresponds to the portions of plate 410 outside of eroded region 420. In other embodiments of the present invention, the spray-deposition gun may be disposed at a non-90° angle to the global surface plane of the plate 410. Whatever the angle at which the spray-deposition gun is disposed, the angle typically is held constant during refurbishment rather than, e.g., changing as a function of local variations in the surface contour of eroded region 420. Thus, complex multi-axis robot systems are typically not required to implement embodiments of the invention; rather, a simple x-y gantry (enabling relative translation of the plate 410 and the spray-deposition gun in the x-y plane depicted in FIG. 4A) is typically sufficient.

In preferred embodiments of the present invention, the depth profile (i.e., measurements of the depth as a function of location therewithin) of eroded region 420 is measured prior to spray-deposition refurbishment of plate 410. For example, a scanning apparatus 430 may be utilized to scan over and measure the depth profile of eroded region 420. Scanning apparatus 430 may include or consist essentially of, for example, a FARO Laser Line Probe on a FARO Edge measurement arm, both available from FARO Technologies Inc. of Lake Mary, Fla. As detailed below, measurement and knowledge of the depth profile of eroded region 420 will enable the spray-deposition process to be controllable as a function of local depth proximate the spray-deposition gun. The information regarding the depth profile of eroded region 420 may be utilized to generate a three-dimensional model of plate 410 that may be utilized to control one or more parameters of the spray-refurbishment process.

FIG. 4B depicts a cross-section of sputtering target 400 along the line 4B-4B in FIG. 4A, and shows plate 410 affixed to a backing plate 440. (As mentioned above, the refurbishment process detailed herein may be performed with plate 410 affixed to the backing plate 440, but backing plate 440 is typically omitted from the remaining figures for clarity.) As shown, the eroded region 420 defines a recessed surface contour 440, and the eroded region 420 has a maximum depth 450 below the surface of plate 410. In accordance with preferred embodiments of the invention, in order that the obliquity angle to the surface contour be maintained in a preferred range (e.g., 45°-90°), the maximum depth is, e.g., less than approximately 9 mm, and preferably less than approximately 6 mm, or even less than approximately 3 mm. Typically the full thickness of plate 410 is approximately 18 mm, so embodiments of the invention involve refurbishing sputtering-target plates when the depth of eroded region 420 is approximately 50% of the total thickness of plate 410. While plates 410 may conventionally be sputtered to greater consumed depths, limiting the maximum depth of eroded region 420 enables, at least in part, the maintenance of favorable obliquity angles and thus enables a less-complex refurbishment process than processes typically required when target material is consumed to much greater depths. (Thus, even though refurbishment in accordance with embodiments of the invention at high obliquity angles and relatively low amounts of total target consumption may require more frequent refurbishment and concomitant expense and equipment down-time, the resulting faster, less complex, and cheaper refurbishment surprisingly, even performed more often, may compensate in terms of overall process costs.)

After the depth information for eroded region 420 has been obtained, the plate 410 may be refurbished by spray deposition. Preferably the spray-deposition process includes or consists essentially of cold spray, and is performed below the melting points of the material of plate 410 (which typically corresponds to the material that is spray deposited to refurbish plate 410) and/or the material of the backing plate 440. Prior to the spray deposition, the surface of the eroded plate 410 may be treated to provide a high-quality, clean, substantially oxide-free interface between the original target material and the newly deposited material. For example, the eroded surface may be grit blasted, machined, and/or etched (e.g., with acid) prior to the spray deposition. After the optional surface treatment, spray deposition is initiated by positioning a spray-deposition gun 500 over the eroded region 420. The spray-deposition gun 500 is a portion of a spray-deposition system (e.g., a cold-spray deposition system), for example, one of the systems described in U.S. Pat. No. 5,302,414, filed on Feb. 2, 1992, U.S. Pat. No. 6,139,913, filed on Jun. 29, 1999, U.S. Pat. No. 6,502,767, filed on May 2, 2001, or U.S. Pat. No. 6,722,584, filed on Nov. 30, 2001, the entire disclosure of each of which is incorporated by reference herein. The spray-deposition gun 500 receives the material to be sprayed (which preferably matches the material of spent plate 410) in powder (i.e., particulate) form, e.g., from a powder feeder (not shown), accelerates the powder, and sprays the powder (typically from a nozzle) in a jet 510 that strikes the surface of eroded region 420 and is deposited as a layer of material. When initiating the refurbishment process, the gun 500 is positioned over a portion of the eroded region 420 such that the obliquity angle is approximately 45° or greater, thus ensuring that the powder is deposited as a layer on the surface rather than deflecting therefrom or adhering poorly as a layer with large amounts of porosity. The density of the deposited layer is typically greater than 97%, and preferably greater than 99%. As the sprayed material is deposited, the gun 500 is translated across the eroded region 420 (e.g., along the x direction in FIG. 4A) and/or, equivalently, the eroded plate 410 is itself translated beneath the gun 500 (i.e., the gun may be held stationary in some embodiments of the invention), generating a dense layer of the target material having a thickness of approximately 100 μm to approximately 500 μm with each pass of the gun 500 over eroded region 420. In an exemplary implementation, the gun 500 is translated over the entire length of the eroded region 420 (e.g., along the x direction in FIG. 4A) for a single deposition pass, and then the gun 500 is translated in an orthogonal direction (e.g., the y direction in FIG. 4A) a short distance before being translated again over the eroded region 420 in the first direction; that is, a single spray-deposition pass is performed over the entire eroded region 420 before a second pass is performed in any part of eroded region 420, and the eroded region 420 is filled pass-by-pass in this manner.

During spray deposition, the obliquity angle between the jet 510 and the surface of eroded region 420 (or the surface of previously sprayed material therein) changes (e.g., with each pass of the gun 500). For example, the obliquity angle may change from a first angle of approximately 45° or greater to an angle of approximately 90°, and then back to an angle of approximately 45° or greater (e.g., an angle approximately equal to the first angle). Thus, the obliquity angle between the jet 510 (and/or gun 500) and the surface of eroded region 410 takes on multiple different values during the spray-deposition refurbishment, but is always greater than approximately 45° to ensure high-quality deposition (e.g., formation of dense layers well-bonded to the plate 410). Furthermore, maintenance of the preferred high obliquity angle enables the use of simple, e.g., rectilinear, movements of the gun 500 relative to the plate 410, rather than complicated non-linear movements and/or complex gun tilts to alter the angle of impingement of jet 510, thereby rendering embodiments of the invention simple, less time consuming, and less expensive.

Preferred embodiments of the invention also take advantage of the depth profile measured prior to spray deposition to control the deposition rate of the sprayed material based on the local depth of the eroded region 420 (i.e., the depth immediately beneath the gun 500), thereby enabling a substantially uniform filling of eroded region 420 across its width (i.e., along the y direction in FIG. 4A) with the same number of passes over each area. (In contrast, a deposition rate held constant across an eroded region 420 having varying depths would result in the sprayed material protruding from the eroded region 420 in some locations but not filling eroded region 420 in other locations after the same number of passes over all locations.) For example, the rate of translation of the gun 500 relative to the plate 410 may be controlled such that more material is deposited over regions of greater initial depth; for a constant flow rate of powder from gun 500, the slower that gun 500 is translated relative to plate 410, the thicker the locally deposited layer. In addition or instead of controlling the translation rate, the rate of flow of powder to gun 500 may be controlled to form thicker layers over regions of greater initial depth; a larger rate of powder flow to the gun 500 (e.g., from a powder feeder) will result in a thicker layer of locally deposited material. The translation rate and/or the powder feed rate may be controlled based on the depth profile of the eroded region 420 measured prior to spray deposition.

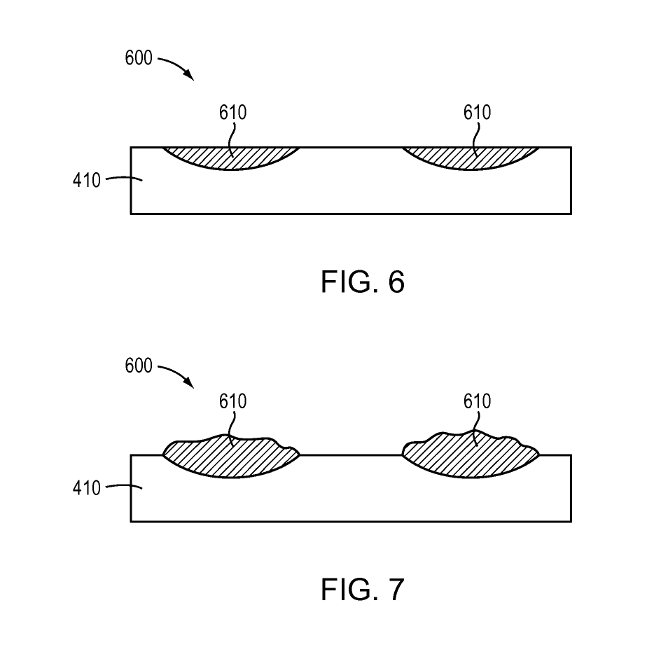

FIG. 6 depicts a refurbished sputtering target 600 that includes or consists essentially of the previously spent plate 410 and spray-deposited material 610 substantially filling the previously eroded regions 420. (Although not shown in FIG. 6, the target 600 may also include backing plate 440 depicted in FIG. 4B.) Spray-deposited material 610 typically includes or consists essentially of unmelted powder of the material of plate 410. As shown in FIG. 6, the surface of material 610 is preferably coplanar with that of the plate 410, thus forming a substantially planar top surface for target 600. As shown in FIG. 7, in some embodiments, portions of the spray-deposited material 610 may protrude from eroded region 420 over the surface of plate 410. Therefore, after spray deposition of material 610, the surface of the target 600 may be planarized (e.g., machined, ground, and/or polished) such that the surfaces of material 610 are coplanar with that of plate 410, as shown in FIG. 6.

After spray-deposition of the material 610 to form the refurbished target 600, the target 600 (at least proximate the material 610) may be heat treated under vacuum for stress relief, to improve ductility, toughness, and bonding (e.g., bond strength), to reduce interstitial gas content, and/or to provide the material 610 with a microstructure substantially equal to that of plate 410 (i.e., the unconsumed and thus unsprayed regions thereof). In some embodiments of the invention, the heat treatment may be performed under vacuum, at a temperature between approximately 700° C. and approximately 1250° C., and for a time between approximately 1 hour and approximately 16 hours.

In addition, the heat treatment may relieve residual stresses from the spray-deposition process. For example, in many cases, sprayed material melted during spraying tends to have tensile residual stress, while sprayed material that is not melted during spraying tends to have compressive residual stress. (For example, cold-sprayed Ta may have residual compressive stress of between 30 and 50,000 psi.) Such residual stresses may result in non-uniform sputtering rates from the target incorporating the sprayed material. In conventional (i.e., not incorporating sprayed material) targets, residual machining stresses frequently necessitate a costly burn-in period (i.e., sputtering away of the stressed surface layer) prior to sputtering with new targets. Embodiments of the present invention described herein facilitate the spray refurbishment of sputtering targets and subsequent heat treatment prior to the plate being joined to a backing plate. (The backing plate and the joining compound, e.g., In solder, typically have lower melting points and thus may not be able to withstand a heat treatment adequate to reduce or substantially eliminate residual stress from the target.) In this manner, the need for a burn-in period prior to sputtering from the joined target is reduced or substantially eliminated.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1.-15. (canceled)

16. A method of refurbishing an eroded sputtering target that comprises a target material, the eroded sputtering target (I) having a non-planar eroded surface region and (ii) defining a global surface plane corresponding to a planar surface of the sputtering target prior to erosion thereof, the method comprising:
measuring a depth profile of the eroded surface region of the eroded sputtering target; and
only if, over the entire eroded surface region, the depth profile defines obliquity angles no less than approximately 45° with respect to a direction normal to the global surface plane:
positioning a spray-deposition gun over the eroded surface, thereby defining a spray-gun angle between the spray-deposition gun and the global surface plane, and
without changing the spray-gun angle, substantially filling the eroded surface region by spray-depositing particles of the target material by (i) translating the spray-deposition gun relative to the eroded sputtering target, whereby the obliquity angle between the spray-deposition gun and the eroded surface region immediately thereunder ranges between approximately 45° and approximately 90° thereduring, and (ii) controlling a deposition rate of the particles of the target material based on a depth of the eroded surface region beneath the spray-deposition gun.

17. The method of claim 16, wherein the depth profile defines obliquity angles no less than approximately 60° with respect to a direction normal to the global surface plane.

18. The method of claim 16, further comprising machining the eroded sputtering target prior to substantially filling the eroded surface region.

19. The method of claim 16, further comprising at least one of grit blasting or etching the eroded sputtering target prior to substantially filling the eroded surface region.

20. The method of claim 16, wherein a maximum surface depth of the eroded sputtering target prior to spray deposition is less than 9 mm.

21. The method of claim 16, wherein a maximum surface depth of the eroded sputtering target prior to spray deposition is less than 6 mm.

22. The method of claim 16, wherein spray-depositing the particles of the target material comprises cold spraying.

23. The method of claim 16, further comprising annealing the sputtering target after substantially filling the eroded surface region.

24. The method of claim 16, wherein substantially filling the eroded surface region comprises overfilling the eroded surface region to form a refurbished sputtering target having a non-planar surface, and further comprising planarizing the surface of the refurbished sputtering target.

25. The method of claim 16, wherein the spray-deposition gun is translated relative to the eroded sputtering target at a substantially constant rate notwithstanding changes in depth of the eroded surface region during spray deposition.

26. The method of claim 16, wherein the spray-deposition gun is translated relative to the eroded sputtering target at a substantially constant rate notwithstanding changes in the obliquity angle during spray deposition.

27. The method of claim 16, wherein controlling the deposition rate of the particles of the target material comprises controlling a rate of the translation of the spray-deposition gun relative to the eroded sputtering target.

28. The method of claim 16, wherein controlling the deposition rate of the particles of the target material comprises controlling a rate of particle flow to the spray-deposition gun.

29. The method of claim 16, wherein the spray-deposition gun is translated relative to the eroded sputtering target only rectilinearly.

30. The method of claim 16, wherein the target material is an alloy or mixture of a plurality of different elements.

31. The method of claim 1, wherein the spray-gun angle is approximately 90°.
